(19) United States
(12) Patent Application Publication
(10) Pub. No.: US 2025/0248076 A1
(43) Pub. Date: Jul. 31, 2025

(54) P-GAN GATE TUNNEL JUNCTION HEMT

(71) Applicant: The Hong Kong University of Science and Technology, Hong Kong (CN)

(72) Inventors: Jing CHEN, Hong Kong (CN); Hang LIAO, Hong Kong (CN); Tao CHEN, Hong Kong (CN)

(21) Appl. No.: 19/026,537

(22) Filed: Jan. 17, 2025

Related U.S. Application Data
(60) Provisional application No. 63/626,534, filed on Jan. 30, 2024.

(51) Int. Cl. H10D 62/10; H10D 30/47; H10D 62/824; H10D 64/23; H10D 64/64

(52) U.S. Cl. CPC H10D 62/102; H10D 30/4732; H10D 30/474; H10D 62/124; H10D 62/824; H10D 64/256; H10D 64/647

(57) ABSTRACT

A p-GaN gate tunnel junction HEMT includes a nucleation layer, buffer layer, nitride-based channel layer, nitride-based barrier layer, p-type GaN layer, gate electrode, source electrode, drain electrode, and surface passivation layer. The nucleation and buffer layers are disposed on a substrate, with the nitride-based channel layer above. The nitride-based barrier layer is positioned on the nitride-based channel layer, creating a 2DEG channel between the channel and barrier layers. The p-type GaN layer is positioned on the nitride-based barrier layer. The gate electrode is positioned on the p-type GaN layer. The source electrode forms a tunnel junction with the 2DEG channel, and the drain electrode is placed on the nitride-based barrier layer. The passivation layer covers the nitride-based barrier layer with portions between the gate-source and gate-drain regions.

### TECHNICAL FIELD

The present invention relates to nitride-based semiconductor devices; and more particularly to p-GaN gate tunnel junction high-electron-mobility transistors (TJ-HEMTs).

### BACKGROUND

In GaN power electronics, GaN HEMTs have initially emerged as depletion-mode (D-mode) devices with the polarization-induced two-dimensional electron gas (2DEG) channel. The high density and high mobility of the 2DEG result in a low on-resistance for D-mode GaN HEMTs. Normally-off or enhancement-mode (E-mode) operation is desired for fail-safe operation and is achieved by incorporating a p-GaN layer to deplete the 2DEG in the gated region. However, the thickness of the AlGaN barrier layer must be limited to ensure a positive threshold voltage (VTH) of p-GaN gate HEMTs. This constraint compromises the 2DEG density in the access region and the on-resistance of p-GaN gate HEMTs. Furthermore, p-GaN gate HEMTs are prone to severe short-channel effects, such as drain-induced barrier lowering (DIBL) and increased off-state leakage with a planar top gate when the gate length is small.

The p-GaN gate HEMT is the mainstream device architecture for GaN-based enhancement-mode (normally-off) power transistors. In this design, the p-GaN gate fully depletes the 2DEG in the gated region at zero gate bias, enabling E-mode operation. However, this approach limits the 2DEG density in the access region, resulting in a trade-off with the device's on-resistance. To address this issue, AlGaN regrowth techniques have been developed, where the access region features a thicker AlGaN layer than the gated region. Nonetheless, this solution increases the complexity and cost of device fabrication.

Short-channel effects in low-voltage HEMTs remain a significant challenge, particularly in managing DIBL and off-state leakage. For p-GaN HEMTs with small gate lengths, a planar top gate struggles to effectively suppress DIBL and fully pinch off the device. While a more complex tri-gate architecture can mitigate these issues, it is less desirable for mass production due to its increased process complexity.

Therefore, there is a need to develop a nitride-based semiconductor device that minimizes on-resistance, mitigates short-channel effects such as DIBL and off-state leakage, and maintains scalability for cost-effective mass production.

### SUMMARY OF INVENTION

It is an objective of the present invention to provide devices to address the aforementioned shortcomings and unmet needs in the state of the art.

In the present invention, a nitride-based device structure is provided, featuring a source tunnel junction and a p-GaN gate for low on-resistance and suppressed short-channel effect. According to one embodiment, a nitride-based device is provided with a p-GaN gate tunnel junction high-electron-mobility transistor (TJ-HEMT). The device has, from the bottom-most, a substrate, a buffer layer arranged over the substrate, a channel layer arranged over the buffer layer, a barrier arranged over the channel layer, and a p-type GaN cap layer.

In accordance with a first aspect of the present invention, a p-GaN gate tunnel junction HEMT with a source-side tunnel junction is provided. The p-GaN gate tunnel junction HEMT includes a nucleation layer, a buffer layer, a nitride-based channel layer, a nitride-based barrier layer, a p-type GaN layer, a gate electrode, a source electrode, a drain electrode, and a surface passivation. The nucleation layer is disposed on a substrate. The buffer layer is disposed on the nucleation layer. The nitride-based channel layer is disposed on the buffer layer. The nitride-based barrier layer is disposed on the nitride-based channel layer with a 2DEG channel formed between the nitride-based channel layer and the nitride-based barrier layer. The p-type GaN layer is disposed on the nitride-based barrier layer. The gate electrode is disposed on the p-type GaN layer. The source electrode is disposed on the nitride-based channel layer and upward extends from the nitride-based channel layer, so as to at least form an interface with a side surface of the nitride-based channel layer and further form a source tunnel junction with the 2DEG channel. The drain electrode is disposed on the nitride-based barrier layer. The surface passivation layer is disposed on the nitride-based barrier layer and has a first portion between the gate electrode and the source electrode and a second portion between the gate electrode and the drain electrode.

By the configuration, the proposed p-GaN gate TJ-HEMT integrates a source tunnel junction with zero gate-to-source length for enhanced performance. The tunnel junction, controlled entirely by the gate and independent of drain bias, effectively suppresses DIBL (drain-induced barrier lowering) and allows for a small planar top gate while minimizing off-state leakage. Moreover, the TJ-HEMT structure supports a higher 2DEG density and achieves lower on-resistance compared to conventional p-GaN HEMTs. The proposed p-GaN gate TJ-HEMT enables enhancement-mode operation with improved device characteristics.

### BRIEF DESCRIPTION OF DRAWINGS

Embodiments of the invention are described in more details hereinafter with reference to the drawings, in which:

FIG. 1 is a vertical cross-sectional view of a p-GaN gate tunnel junction HEMT according to some embodiments of the invention;

FIG. 2A shows a schematic cross-section view for a p-GaN gate tunnel junction HEMT according to some embodiments of the present invention;

FIG. 2B shows band diagrams along a cut line of the p-GaN gate tunnel junction HEMT of FIG. 2A at different V_{GS} where V_{GS1}<V_{GS2}<V_{GS3};

FIG. 3A shows a schematic cross-section view for a p-GaN gate tunnel junction HEMT according to some embodiments of the present invention;

FIG. 3B shows band diagrams along a cut line of the p-GaN gate tunnel junction HEMT of FIG. 3A at high V_{GS};

FIG. 4 is a vertical cross-sectional view of a p-GaN gate tunnel junction HEMT device according to some embodiments of the invention;

FIG. 5 is a vertical cross-sectional view of a p-GaN gate tunnel junction HEMT according to some embodiments of the invention;

FIG. 6 is a vertical cross-sectional view of a p-GaN gate tunnel junction HEMT according to some embodiments of the invention;

FIG. 7 is a vertical cross-sectional view of a p-GaN gate tunnel junction HEMT according to some embodiments of the invention;

FIG. 8 is a vertical cross-sectional view of a p-GaN gate tunnel junction HEMT according to some embodiments of the invention.

### DETAILED DESCRIPTION OF THE INVENTION

In the following description, p-GaN gate tunnel junction HEMTs and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

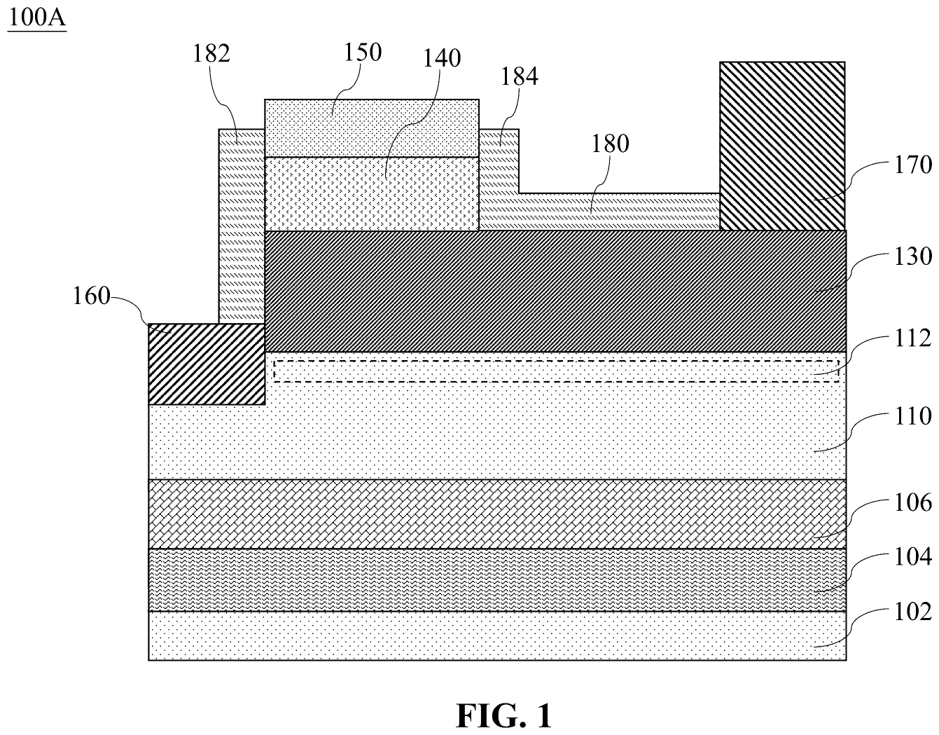

FIG. 1 is a vertical cross-sectional view of a p-GaN gate tunnel junction HEMT 100A according to some embodiments of the invention. The p-GaN gate tunnel junction HEMT 100A includes a substrate 102, a nucleation layer 104, a buffer layer 106, a nitride-based channel layer 110, a nitride-based barrier layer 130, a p-type GaN layer 140, a gate electrode 150, a source electrode 160, a drain electrode 170, and a surface passivation layer 180.

The substrate 102 is a semiconductor substrate. For example, the substrate 102 may be made of materials such as Si, SiGe, SiC, gallium arsenide, p-doped Si, n-doped Si, sapphire, diamond, or semiconductor-on-insulator materials such as silicon-on-insulator (SOI), or other suitable substrate materials. In some embodiments, the substrate 102 may include group III elements, group IV elements, group V elements, or combinations thereof (e.g., III-V compounds) such as AIN and GaN. In other embodiments, the substrate 102 may include one or more features, such as a doped region, a buried layer, an epitaxial (epi) layer, or combinations thereof.

The nucleation layer 104 is disposed on the substrate 102, and the buffer layer 106 disposed on the nucleation layer 104. The nucleation layer 104 is formed between the substrate 102 and the buffer layer 106. The nucleation layer 102 can provide a transition to accommodate a mismatch/difference between the substrate 102 and the buffer layer 106 which includes a III-nitride material. The exemplary material of the nucleation layer 104 may include AlN, GaN, InN, or any of their alloys. The buffer layer 106 is formed to reduce lattice and thermal mismatches between the substrate 102 and the nitride-based channel layer 110, thereby curing defects due to the mismatches/difference. The buffer layer 106 may include a III-V compound, including aluminum, gallium, indium, nitrogen, or combinations thereof. In some embodiments, materials of the buffer layer 106 may further include, AlN, GaN, InN, AlGaN, InAlGaN, or combinations thereof.

The nitride-based channel layer 110 is disposed on the buffer layer 106. The nitride-based barrier layer 130 is disposed on the nitride-based channel layer 110. Nitride-based materials of the nitride-based channel layer 110 may include nitrides or group III-V compounds, such as AlN, GaN, InN, or their alloys. For example, the nitride-based materials of the nitride-based channel layer 110 may further include InₓAl_{y}Ga_{(1-x-y)}N where x+y≤1, Al_{y}Ga_{(1-y)}N where y≤1. Nitride-based materials of the nitride-based barrier layer 130 may include binary III-nitride compound, ternary III-nitride, quaternary III-nitride, AlN, AlGaN, InAlN, InAlGaN, or combinations thereof, such as InₓAl_{y}Ga_{(1-x-y)}N where x+y≤1, Al_{y}Ga_{(1-y)}N where y≤1. The nitride-based barrier layer 130 may be formed using one single layer or a stack of layers. For example, the nitride-based barrier 130 could be AlN, GaN, InN, or their alloys. Similarly, the nitride-based materials of the nitride-based barrier layer 130 may further include InₓAl_{y}Ga_{(1-x-y)}N where x+y≤1, Al_{y}Ga_{(1-y)}N where y≤1. The nitride-based materials of the nitride-based barrier layer 130 may further include a III-V mobility enhancement layer (MEL). The III-V MEL enhances electron mobility by reducing scattering effects at the interface. Moreover, the III-V MEL can optimize the band structure at the channel-barrier interface, contributing to higher 2DEG density and improved conductivity. In some embodiments, the III-V MEL is a binary III-nitride compound layer including AlN, InN, or combinations thereof.

As a HEMT device, the materials for the nitride-based semiconductor layers 104 and 106 are chosen such that the bandgap of the nitride-based barrier layer 130 is greater than that of the nitride-based channel layer 110. This difference in bandgap results in distinct electron affinities, forming a heterojunction between the two layers. This configuration allows the channel layer and barrier layer to function as intended, creating a triangular potential well at their interface. Electrons accumulate in this well, forming a two-dimensional electron gas (2DEG) channel 112 adjacent to the heterojunction. As a result, the p-GaN gate tunnel junction HEMT 100A can incorporate at least one GaN-based high-electron-mobility transistor (HEMT).

The p-type GaN layer 140 is disposed on top of the nitride-based barrier layer 130, with the gate electrode 150 disposed on the top of p-type GaN layer 140. The gate electrode 150 can form a Schottky or ohmic contact with the p-type GaN layer 140. The p-GaN gate tunnel junction HEMT 100A can operate in enhancement mode and remain in a normally-off state when the gate electrode 150 is at approximately zero bias. The p-type GaN layer 140 forms at least one p-n junction with the nitride-based barrier layer 130. The 2DEG channel 112 in the region beneath the gate electrode 150 could remain conductive. However, the present invention is not limited to this operation mode. The desired threshold voltage is adjustable according to device requirements.

The p-type GaN layer 140 is a p-type doped III-V semiconductor layer. In some embodiments, the p-doped materials are achieved by using a p-type impurity, such as Be, Mg, Zn, Cd, and Mg. In some embodiments, the p-type GaN layer 140 can be replaced by using other p-type materials, including p-type GaN, p-type AlGaN, p-type InN, p-type AlInN, p-type InGaN, p-type AlInGaN, or combinations thereof. The gate electrode 150 can be made by metal, metal alloy, metal nitride, or heavily doped semiconductors. Conductive materials of the gate electrode 150 may include Ni, Ti, Au, Mo, W, Al, Cu, Ag, Cr, TIN, TiW, ITO, or combinations thereof.

The source electrode 160 and the drain electrode 170 are formed over the nitride-based channel layer 110 and the nitride-based barrier layer 130. The p-type GaN layer 140 and the gate electrode 150 are located between the source electrode 160 and the drain electrode 170. The bottom surface of the source electrode 160 makes contact with the nitride-based channel layer 110 and the bottom surface of the drain electrode 170 makes contact with the nitride-based barrier layer 130.

The source electrode 160 is positioned on the nitride-based channel layer 110 and upward extends from the nitride-based channel layer 110 to at least form an interface with a side surface of the nitride-based channel layer 110, thereby forming a contact to at least one heterojunction channel between the nitride-based channel layer 110 and the nitride-based barrier layer 130. In this regard, the nitride-based channel layer 110 has a recess with a bottom surface holding the bottom of the source electrode. Also, the source electrode 160 is optionally formed to make contact with the nitride-based barrier layer 130. In some embodiments, the source electrode 160 is made by metal, metal alloys, or silicides. As such, the source electrode 160 forms a Schottky contact with the 2DEG channel 112. This metal-2DEG Schottky junction is also a source-side tunnel junction. In some embodiments, the source electrode 160 is made by heavily-doped p-type binary III-V nitride, ternary III-V nitride, quaternary III-V nitride, polysilicon, metal oxide semiconductors, or other heavily-doped p-type semiconductor materials. As such, the source electrode 160 forms a p-n junction with the 2DEG channel. The height of the source electrode 160 is adjustable. For example, the source electrode 160 can extend to a position higher or lower than the bottom surface of the p-type GaN layer 140. The source electrode 160 may be formed as a single layer, or plural layers of the same or different composition.

In some embodiments, the drain electrode 170 may include metals, alloys, doped semiconductor materials (such as doped crystalline silicon), compounds such as silicides and nitrides, other conductor materials, or combinations thereof. In some embodiments, conductive materials of the drain electrode 170 may include Ni, Ti,

Al, Cu, Ag, Au, W, Cr, TiN, TiW, ITO, or combinations thereof. In some embodiment, the drain electrode 170 is formed to have ohmic contact, including Ti/Al/TiN, Ti/Al/Ni/Au, Ti/Al/Ti/Au, Ti/Au or combinations thereof. The drain electrode 170 may be formed as a single layer, or plural layers of the same or different composition.

The dielectric layer 180 has a first portion 182 and a second portion 184 separated than each other by the p-type GaN layer 140 and the gate electrode 150. The first portion 182 is located on the source electrode 160 and extends upward to make contact with sidewalls of the nitride-based barrier layer 130, the p-type GaN layer 140, and the gate electrode 150. The left sidewall of the nitride-based channel layer 110 is entirely covered with the first portion 182 and the source electrode 160. The left sidewall of the p-type GaN layer 140 is entirely covered with the first portion 182 for an electrical isolation purpose. The second portion 184 is located between the gate electrode 150 and the drain electrode 170 and covers the nitride-based barrier layer 130. Materials of the dielectric layer 180 may be a single layer and include SiO₂, Al₂O₃, AlN, AlON, SiNₓ, oxides, nitrides, or combinations thereof. In some embodiments, the dielectric layer 180 is a multi-layered structure, such as a composite dielectric layer of Al₂O₃/SiN, Al₂O₃/SiO₂, AlN/SiNx, AlN/SiO₂, or combinations thereof.

This configuration implements a p-GaN gate TJ-HEMT structure, optimizing on-resistance and addressing the short-channel effect in conventional p-GaN gate HEMT device. The TJ-HEMT structure features a tunnel junction (e.g., metal-2DEG tunnel junction) at the source side, located near/at the interface between the 2DEG channel 112 of the nitride-based channel layer 110 and the source electrode 160. Because the tunnel junction is entirely controlled by the gate electrode 150 and is nearly independent of drain bias (e.g., the bias applied to the drain electrode 170), the issue of drain-induced barrier lowering (DIBL) is effectively mitigated. In the off-state, with zero or negative gate bias (e.g., applied to the gate electrode 150), the tunnel junction provides reverse-blocking capability, resulting in extremely low off-state leakage regardless of gate length.

The TJ-HEMT structure operates based on modulation of the Schottky barrier thickness by the gate voltage (VGS). When VGS exceeds the threshold voltage (VTH), electrons tunnel through the thin barrier from the source metal to the 2DEG channel. Unlike conventional p-GaN HEMTs, in the p-GaN gate tunnel junction HEMT 100A, VTH is determined by the tunnelling process and is only weakly dependent on the 2DEG density in the gated region. Consequently, a thicker AlGaN (e.g., the nitride-based barrier layer 130) can be used to achieve a higher 2DEG density, thereby reducing on-resistance while maintaining E-mode operation. For example, in some embodiments, the nitride-based barrier layer 130 may be a 20-nm-thick Al_{0.25}Ga_{0.75}N layer. Additionally, the zero gate-to-source distance in the TJ-HEMT structure further contributes to lower on-resistance.

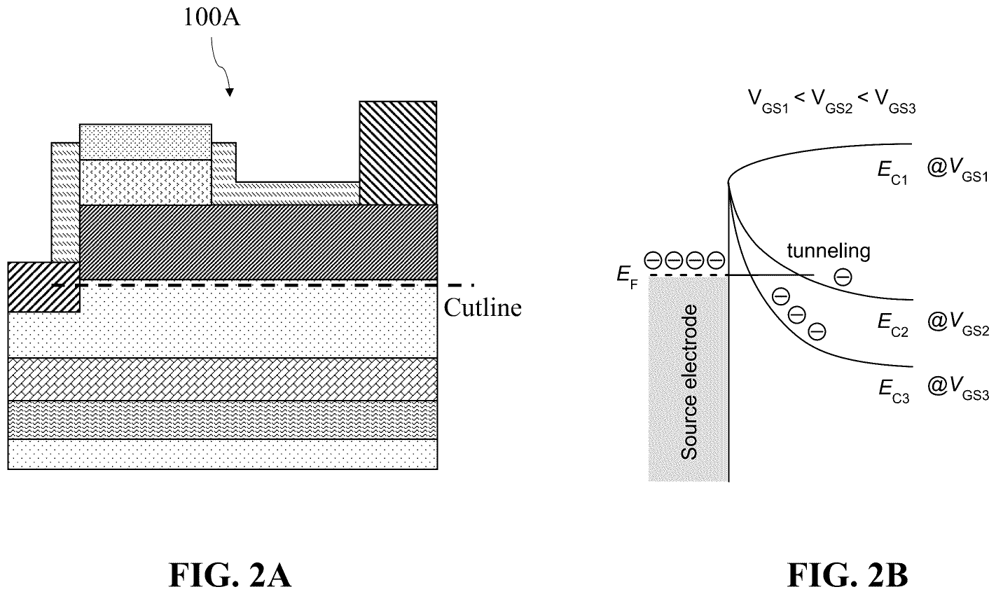

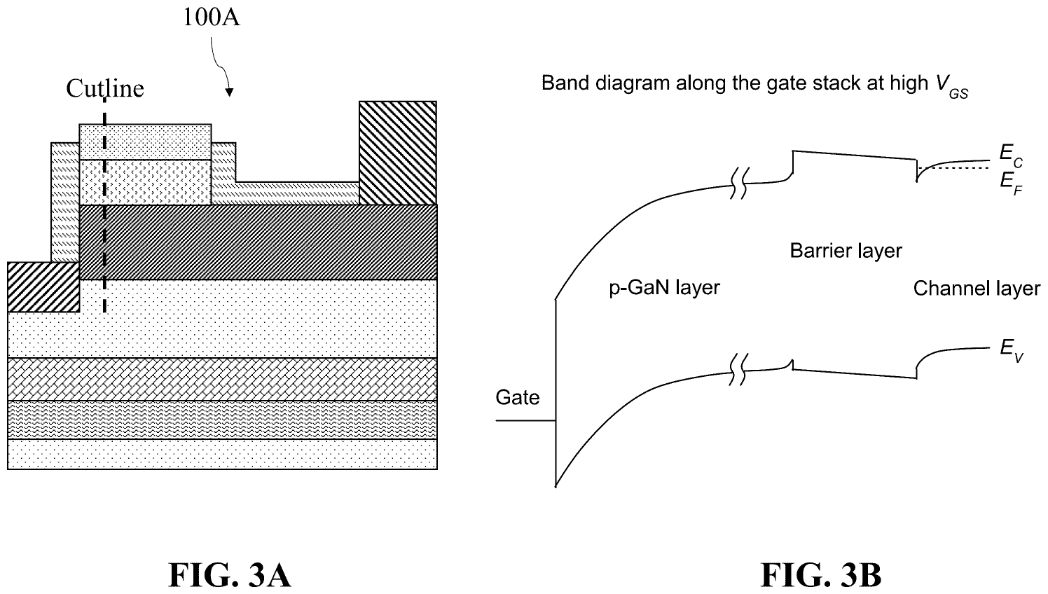

FIG. 2A shows a schematic cross-section view for a p-GaN gate TJ-HEMT according to some embodiments of the present invention; FIG. 2B shows band diagrams along a cut line of the p-GaN gate TJ-HEMT of FIG. 2A at different VGs where V_{GS1}<V_{GS2}<V_{GS3}. The p-GaN gate TJ-HEMT applies the configuration as afore-described. E_{c1}, E_{c1}, E_{c3} correspond with V_{GS1}<0 V, V_{GS2}=0 V, V_{GS3}>0 V. FIG. 3A shows a schematic cross-section view for a p-GaN gate TJ-HEMT according to some embodiments of the present invention; FIG. 3B shows band diagrams along a cut line of the p-GaN gate TJ-HEMT of FIG. 3A at high V_{GS}. The performance graphs of these examples demonstrate the aforementioned benefits and improvements.

As shown in the illustrations, tunneling-based current conduction for TJ-HEMT is demonstrated. As the gate-to-source voltage (V_{GS}) increases, the barrier thickness is narrowed, facilitating electron transport. The illustrations show the energy band diagram of the p-GaN layer, barrier layer, and channel layer under high gate bias conditions.

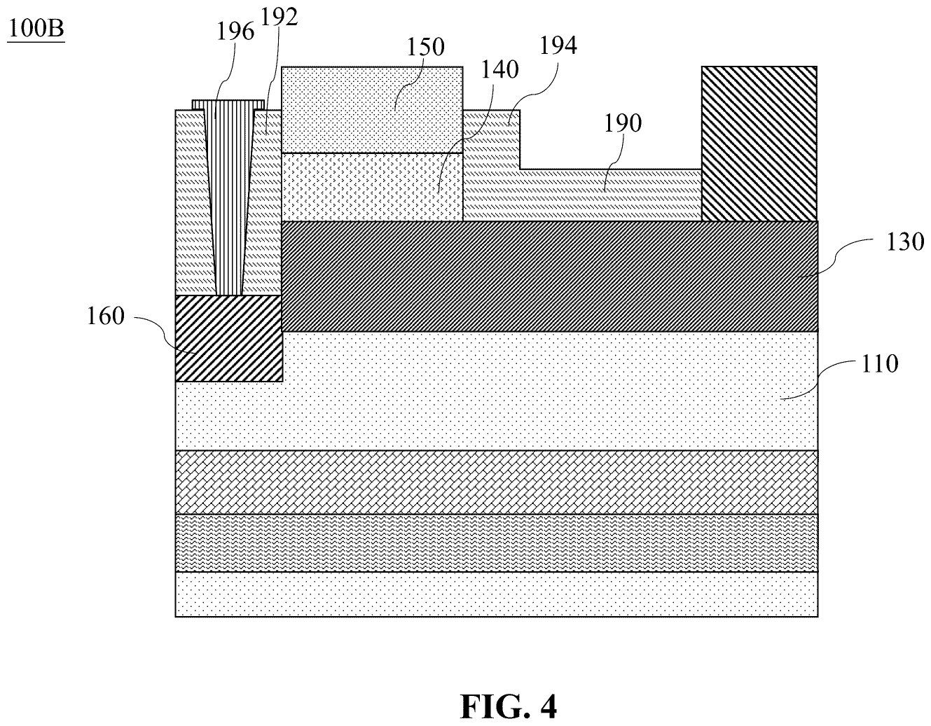

FIG. 4 is a vertical cross-sectional view of a p-GaN gate tunnel junction HEMT 100B according to some embodiments of the invention. The p-GaN gate tunnel junction HEMT 100B has a configuration similar to that of the p-GaN gate tunnel junction HEMT 100A, except that the source electrode 160 of the p-GaN gate tunnel junction HEMT 100B is shorter.

Specifically, the source electrode 160 has a top surface positioned lower than a top surface of the nitride-based barrier layer 130.

The first portion 192 of the surface passivation layer 190 extends from the top surface of the source electrode 160 to the gate electrode 150, with the first portion 192 covering side surfaces of the nitride-based barrier layer 130 and the p-type GaN layer 140. Correspondingly, the source electrode 160 is buried in the first portion 192 of the surface passivation layer 190. The p-GaN gate tunnel junction HEMT 100B further includes a source via contact 196 disposed within the first portion 192 of the surface passivation layer 190 and in contact with the source electrode 160. The source via contact 190 can extend upward to a position higher than the p-type GaN layer 140.

In some embodiment, the source via contact 196 and the source electrode 160 have different conductive materials. For example, the source electrode 160 is designed to form a tunnel junction, and thus the material selection may consider properties such as work function, chemical stability, and the ability to establish an efficient tunneling effect with the 2DEG layer, ensuring the formation of Schottky contact with the 2DEG channel. In contrast, the source via contact 196 has robust electrical conductivity and a reliable connection with the source electrode 160 while maintaining compatibility with the overall fabrication process.

The structure for the gate and source in TJ-HEMT devices can have the following variations according to process conditions and device performance requirements.

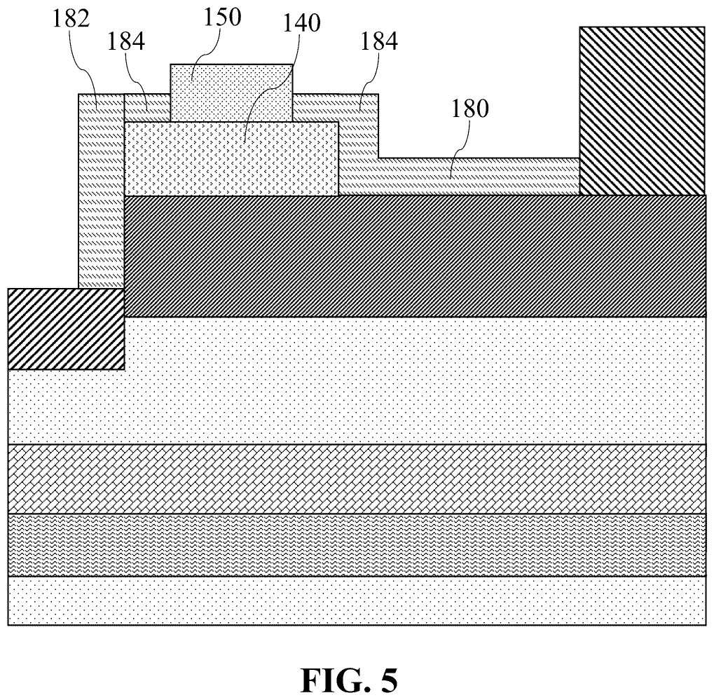

FIG. 5 is a vertical cross-sectional view of a p-GaN gate tunnel junction HEMT 100C according to some embodiments of the invention. The p-GaN gate tunnel junction HEMT 100C has a configuration similar to that of the p-GaN gate tunnel junction HEMT 100A, except that the gate electrode 150 is non-self-aligned. The second portion 184 of the dielectric layer 180 further extends to the top surface of the p-type GaN layer 140 to enclose sidewalls of the gate electrode 150. Moreover, the first portion 182 and the second portion 184 of the dielectric layer 180 are connected to each other.

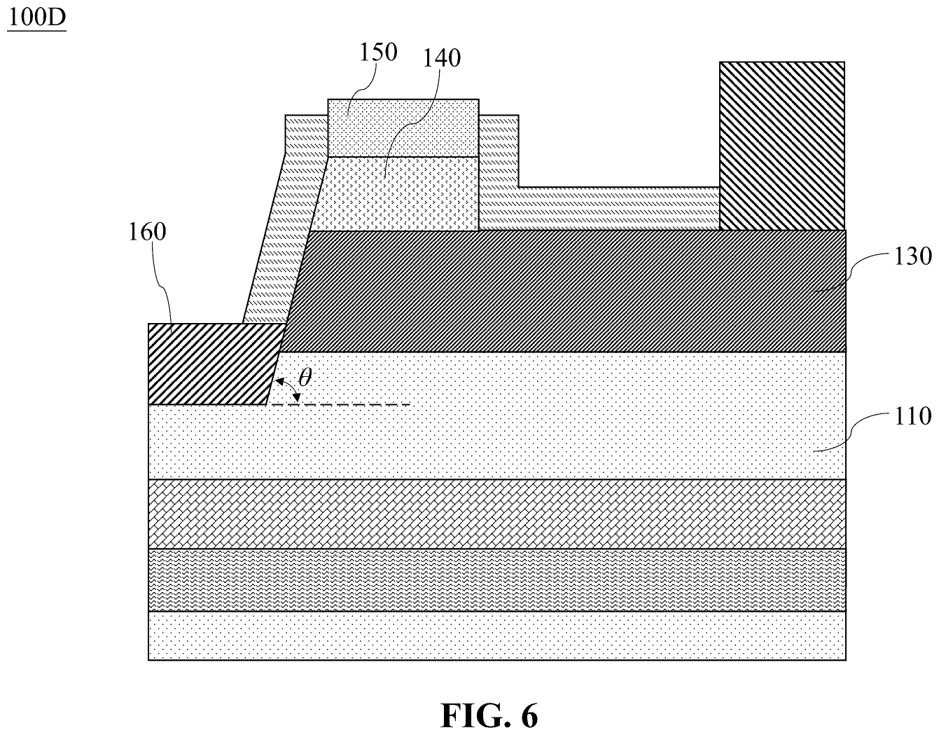

FIG. 6 is a vertical cross-sectional view of a p-GaN gate tunnel junction HEMT100D according to some embodiments of the invention. The p-GaN gate tunnel junction HEMT 100D has a configuration similar to that of the p-GaN gate tunnel junction HEMT 100A, except that the sidewall at the source-side tunnel junction has an angle of θ (θ<90 degrees). Specifically, the source-side sidewalls of the nitride-based channel layer 110, the nitride-based barrier layer 130, and the p-GaN layer 140 have an angle of θ (0<θ<90 degrees). The source electrode 160 contacts the heterojunction channel, which forms a sloped interface. As such, the equivalent contact area between the source electrode 160 and heterojunction channel/junction is enlarged. Furthermore, the gate electrode 150 is self-aligned.

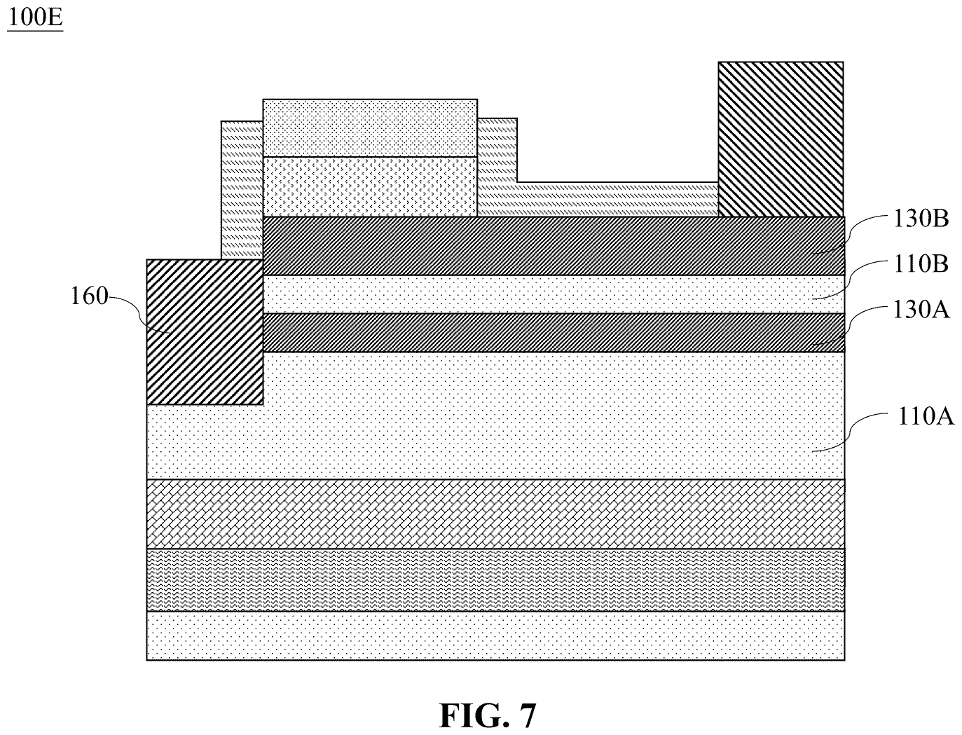

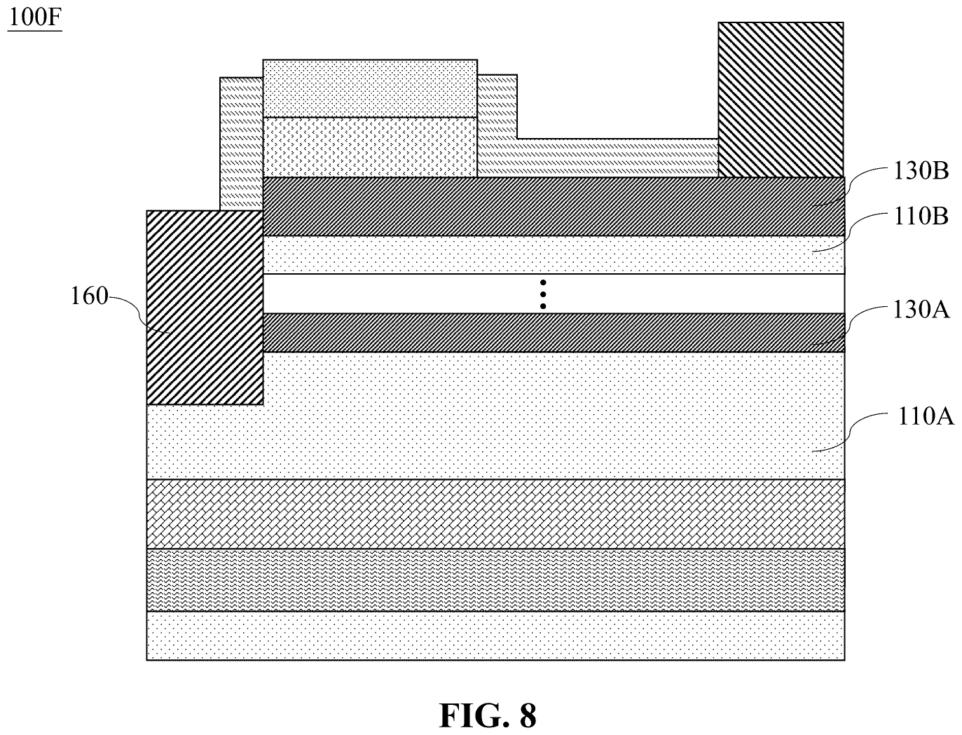

FIG. 7 is a vertical cross-sectional view of a p-GaN gate tunnel junction HEMT 100E according to some embodiments of the invention. The p-GaN gate tunnel junction HEMT 100E has a configuration similar to that of the p-GaN gate tunnel junction HEMT 100A, except that the p-GaN gate tunnel junction HEMT 100E has a double-channel structure. The p-GaN gate tunnel junction HEMT 100E includes nitride-based channel layers 110A, 110B and nitride-based barrier layers 130A, 130B.

From the nitride-based channel layer 110A, there are the nitride-based barrier layer 130A, the nitride-based channel layer 110B, and the nitride-based barrier layer 130B arranged in sequence, thereby forming the double-channel structure. In the double-channel structure, the barrier layer and the channel layer in each heterojunction channel could have different thicknesses; for example, the nitride-based channel layer 110B and the nitride-based barrier layer 130B may have different thicknesses; or, the nitride-based barrier layers 130A and 130B may have different thicknesses.

The source electrode 160 contacts the two heterojunction channels, including a lower heterojunction channel formed between the nitride-based channel layer 110A and the nitride-based barrier layer 130A and a higher heterojunction channel formed between the nitride-based channel layer 110B and the nitride-based barrier layer 130B. The source electrode 160 has a top surface in a position higher than the bottom surface of the nitride-based barrier layer 130B and lower than the top surface of the nitride-based barrier layer 130B. Furthermore, the gate electrode 150 is self-aligned.

FIG. 11 is a vertical cross-sectional view of a p-GaN gate tunnel junction HEMT 100F according to some embodiments of the invention. The p-GaN gate tunnel junction HEMT 100F has a configuration similar to that of the p-GaN gate tunnel junction HEMT 100E, except that the p-GaN gate tunnel junction HEMT 100F has a multiple-channel structure. The p-GaN gate tunnel junction HEMT 100F includes nitride-based channel layers 110A, 110B and nitride-based barrier layers 130A, 130B. One or more stacks of channel and barrier layers are positioned between the nitride-based barrier layer 130A and the nitride-based channel layer 110B, in which each stack includes one nitride-based channel layer and one nitride-based barrier layer form a heterojunction channel therebetween. As such, the multiple-channel structure is established. The barrier layer and the channel layer in each stack could have different thicknesses with others. For example, two of the barrier layers (or the channel layers) in the multiple-channel structure may have different thicknesses.

The source electrode 160 contacts the multiple heterojunction channels. In various embodiments, the number of the heterojunction channels in the single p-GaN gate tunnel junction HEMT 100F is greater than or equal to three. The source electrode 160 has a top surface in a position higher than the bottom surface of the nitride-based barrier layer 130B and lower than the top surface of the nitride-based barrier layer 130B (i.e., the topmost one of the barrier layers). Furthermore, the gate electrode 150 is self-aligned.

From these variations, it can be seen that the zero gate-to-source length configuration of the present invention can have multiple implementations to meet different needs or scenarios.

In this invention, the TJ-HEMT features a source tunnel junction controlled by a p-GaN gate and zero gate-to-source length. Due to the weak dependence of the tunneling junction's turn-on and turn-off behavior on the drain bias, the proposed structure addresses DIBL issue that occurs in conventional p-GaN gate HEMTs when the gate dimensions are scaled down. Therefore, the gate length can be further reduced while maintaining a low off-state current. Compared to conventional p-type GaN gate HEMTs, the TJ-HEMT in the present invention can also achieve a higher 2DEG density and a lower on-resistance.

As discussed above, the TJ-HEMT features a source tunnel junction controlled by a p-GaN gate and a zero gate-to-source length. The DIBL is addressed because the status of the tunnel junction is independent of the drain bias. Additionally, the tunnel junction's intrinsic reverse-blocking capability allows for a smaller gate length while effectively suppressing off-state leakage. Furthermore, the TJ-HEMT achieves a higher 2DEG density and lower on-resistance compared to conventional designs.

Spatial references such as “on,” “above,” “below,” and similar terms are defined relative to a component or plane as shown in the figure. These terms are for illustration only and do not limit the actual arrangement, provided the described embodiments retain their intended benefits.

It should be noted that while various structures are depicted as approximately rectangular in the illustrations, their actual shapes may differ in practice due to fabrication conditions. These shapes may include curves, rounded edges, or variations in thickness. The use of straight lines and right angles in the figures is merely a representational convenience for depicting layers and features.

In this disclosure, the terms “a,” “an,” and “the” should be interpreted to include both singular and plural forms unless explicitly specified otherwise by the context. Additionally, when describing embodiments, a component positioned “on” or “over” another component can refer to cases where the two components are directly in contact or where one or more intermediate components are situated between them.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. A p-GaN gate tunnel junction HEMT, comprising:
a substrate;
a nucleation layer disposed on the substrate;
a buffer layer disposed on the nucleation layer;
at least one nitride-based channel layer disposed on the buffer layer;
at least one nitride-based barrier layer disposed on the nitride-based channel layer with a two-dimensional electron gas (2DEG) channel formed between the nitride-based channel layer and the nitride-based barrier layer;
a p-type GaN layer disposed on the nitride-based barrier layer;
a gate electrode disposed on the p-type GaN layer;
a source electrode disposed on the nitride-based channel layer and upward extending from the nitride-based channel layer to at least form an interface with a side surface of the nitride-based channel layer and further form a source tunnel junction with the 2DEG channel;
a drain electrode disposed on the nitride-based barrier layer; and
a surface passivation layer disposed on the nitride-based barrier layer and having a first portion between the gate electrode and the source electrode and a second portion between the gate electrode and the drain electrode.

2. The p-GaN gate tunnel junction HEMT according to claim 1, wherein the source electrode forms a Schottky contact with the 2DEG channel, and the source electrode and the 2DEG channel form a metal/2DEG tunnel junction.

3. The p-GaN gate tunnel junction HEMT according to claim 1, wherein the source electrode further extends to form an interface with the nitride-based barrier layer.

4. The p-GaN gate tunnel junction HEMT according to claim 3, wherein the gate electrode and the source electrode cover the first portion of the surface passivation layer.

5. The p-GaN gate tunnel junction HEMT according to claim 4, wherein the nitride-based channel layer has a recess with a bottom surface holding the bottom of the source electrode.

6. The p-GaN gate tunnel junction HEMT according to claim 1, wherein the source electrode has a top surface positioned lower than a top surface of the nitride-based barrier layer.

7. The p-GaN gate tunnel junction HEMT according to claim 6, wherein the first portion of the surface passivation layer extends from the top surface of the source electrode to the gate electrode with covering side surfaces of the nitride-based barrier layer and the p-type GaN layer.

8. The p-GaN gate tunnel junction HEMT of claim 1, wherein the nitride-based barrier layer comprises at least one binary III-nitride compound, ternary III-nitride, quaternary III-nitride, AlN, AlGaN, InAlN, InAlGaN, or combinations thereof.

9. The p-GaN gate tunnel junction HEMT of claim 1, wherein the nitride-based barrier layer further comprises a mobility enhancement layer (MEL).

10. The p-GaN gate tunnel junction HEMT of claim 9, wherein the mobility enhancement layer (MEL) is a binary III-nitride compound laying comprising AlN, InN, or combinations thereof.

11. The p-GaN gate tunnel junction HEMT of claim 1, wherein the surface passivation layer comprises at least one layer of SiO₂, Al₂O₃, AlN, AlON, GaON, SiNx, or combinations thereof.

12. The p-GaN gate tunnel junction HEMT of claim 1, wherein the source electrode and the drain electrode have different metal materials.

13. The p-GaN gate tunnel junction HEMT of claim 1, wherein the source electrode is made by metal, metal alloy, metal nitride, binary III-nitride compound, ternary III-nitride, quaternary III-nitride, polysilicon, metal oxide semiconductors, or combinations thereof.

14. The p-GaN gate tunnel junction HEMT of claim 13, wherein the source electrode is buried in the first portion of the surface passivation layer, and the p-GaN gate tunnel junction HEMT further comprises a source via contact disposed within the first portion of the surface passivation layer and in contact with the source electrode.

15. The p-GaN gate tunnel junction HEMT of claim 14, wherein the source via contact and the source electrode have different conductive materials and form an interface therebetween.

16. The p-GaN gate tunnel junction HEMT of claim 14, wherein the source via contact upward extends to a position higher than the p-type GaN layer.

17. The p-GaN gate tunnel junction HEMT of claim 1, wherein sidewalls of the nitride-based channel layer and the nitride-based barrier layer at the source metal-2DEG tunnel junction has an angle greater than 0 degrees and less than 90 degrees.

18. The p-GaN gate tunnel junction HEMT of claim 17, wherein the interface formed by the source electrode with side surfaces of the nitride-based channel layer and the nitride-based barrier layer is sloped.

19. The p-GaN gate tunnel junction HEMT of claim 1, wherein the number of the nitride-based channel layers and the nitride-based barrier layers is each more than one, enabling formation of a double-channel or multiple-channel structure above the buffer layer with more than one 2DEG channel, and wherein the source electrode contacts with the more than one 2DEG channels.

20. The p-GaN gate tunnel junction HEMT of claim 19, wherein the two adjacent nitride-based channel and barrier layers have different thicknesses.

21. The p-GaN gate tunnel junction HEMT of claim 1, wherein the nitride-based barrier layer has a left sidewall entirely covered with the first portion of the surface passivation layer and the source electrode, and the p-type GaN layer has a left sidewall entirely covered with the first portion of the surface passivation layer.

22. The p-GaN gate tunnel junction HEMT of claim 21, wherein the first portion of the surface passivation layer has a bottom surface in contact with a top surface of the source electrode.
